(19) United States
(12) Patent Application Publication
(10) Pub. No.: US 2026/0090234 A1
(43) Pub. Date: Mar. 26, 2026

(54) DISPLAY DEVICE, ELECTRONIC DEVICE AND MANUFACTURING METHOD OF DISPLAY DEVICE

(71) Applicant: Samsung Display Co., LTD., Yongin-si (KR)

(72) Inventor: YOUNGJAE JEON, Yongin-si (KR)

(21) Appl. No.: 19/093,817

(22) Filed: Mar. 28, 2025

(30) Foreign Application Priority Data
Sep. 20, 2024 (KR) 10-2024-0127719

(51) Int. Cl. H10K 59/80; H10K 59/12; H10K 71/60; H10K 102/00; H10K 102/10

(52) U.S. Cl. CPC H10K 59/80517; H10K 59/1201; H10K 59/80518; H10K 71/60; H10K 2102/103; H10K 2102/351

(57) ABSTRACT

A display device includes a substrate, a circuit layer, lower electrodes, a display element layer, and an upper electrode. A plurality of light-emitting regions is defined on the substrate. The circuit layer is disposed on the substrate and includes thin-film transistors. The lower electrodes is disposed on the circuit layer and electrically connected to the thin-film transistors. The lower electrodes is arranged to correspond, respectively, to the light-emitting regions. The display element layer is disposed on the lower electrodes. The upper electrode is disposed on the display element layer. A first lower electrode among the lower electrodes includes a first central region and a first peripheral region surrounding the first central region, which are defined therein, and a thickness of the first central region of the first lower electrode is smaller than a thickness of the first peripheral region of the first lower electrode.

This application claims priority to Korean Patent Application No. 10-2024-0127719, filed on Sep. 20, 2024, and all the benefits accruing therefrom under 35 U.S. C. § 119, the content of which in its entirety is herein incorporated by reference.

### BACKGROUND

### 1. Field

The disclosure relates to a display device and a method of manufacturing the display device, and more specifically, to a display device that enhances light extraction efficiency and a method of manufacturing the display device.

### 2. Description of the Related Art

Organic light-emitting display devices, which possess self-emissive properties, may not include a separate light source, unlike liquid crystal display devices. Accordingly, such organic light-emitting display devices may have various desired such as lightweight, thin thickness, wide viewing angles, fast response speed, and low power consumption, such that the organic light-emitting display devices are widely used in various fields.

### SUMMARY

In organic light-emitting display devices that realize full color, light extraction efficiency may vary with changes in optical length. In organic light-emitting display devices, the optical resonance structure may differ for each of the red, green, and blue light-emitting regions, such that the maximum efficiency may not be achieved for each of these red, green, and blue light-emitting regions.

Embodiments of the disclosure provide a display device with improved light efficiency and a manufacturing method thereof.

A display device according to an embodiment of the disclosure includes a substrate, a circuit layer, lower electrodes, a display element layer, and an upper electrode. In such an embodiment, a plurality of light-emitting regions are defined on the substrate. In such an embodiment, the circuit layer is disposed on the substrate and includes thin-film transistors, the lower electrodes is disposed on the circuit layer and electrically connected to the thin-film transistors, and the lower electrodes are disposed to correspond, respectively, to the light-emitting regions. In such an embodiment, the display element layer is disposed on the lower electrodes, and the upper electrode is disposed on the display element layer.

In such an embodiment, a first lower electrode among the lower electrodes includes a first central region and a first peripheral region, which surrounds the first central region, which are defined therein, and a thickness of the first central region of the first lower electrode is smaller than a thickness of the first peripheral region of the first lower electrode.

According to an embodiment of the disclosure, the first lower electrode may include a first protective layer, a first reflective layer, and a first conductive layer. In such an embodiment, the first reflective layer may be disposed on the first protective layer, and the first conductive layer may be disposed on the first reflective layer. In such an embodiment, the first conductive layer may include a first central conductive layer overlapping the first central region and a first peripheral conductive layer overlapping the first peripheral region. In such an embodiment, the first central conductive layer may have a smaller thickness than the first peripheral conductive layer.

According to an embodiment of the disclosure, the first conductive layer may include indium tin oxide (ITO).

According to an embodiment of the disclosure, the display device may further include a pixel defining layer disposed between the circuit layer and the display element layer. In such an embodiment, the pixel defining layer may cover the first peripheral conductive layer and a portion of the first central conductive layer connected to the first peripheral conductive layer.

According to an embodiment of the disclosure, a second lower electrode among the lower electrodes may include a second central region and a second peripheral region surrounding the second central region, which are defined thereon, and a thickness of the second central region of the second lower electrode may be smaller than a thickness of the second peripheral region of the second lower electrode. In such an embodiment, the thickness the second central region of the second lower electrode may be greater than the thickness of the first central region of the first lower electrode.

According to an embodiment of the disclosure, the thickness of the first peripheral region of the first lower electrode may be equal to the thickness of the second peripheral region of the second lower electrode.

According to an embodiment of the disclosure, the first lower electrode may be disposed to correspond to a first light-emitting region among the plurality of light-emitting regions, and the second lower electrode may be disposed to correspond to a second light-emitting region among the plurality of light-emitting regions. In such an embodiment, the first light-emitting region may emit light in the green wavelength band, and the second light-emitting region may emit light in the blue wavelength band.

According to an embodiment of the disclosure, the second lower electrode may include a second protective layer, a second reflective layer, and a second conductive layer. In such an embodiment, the second reflective layer may be arranged on the second protective layer, and the second conductive layer may be arranged on the second reflective layer. In such an embodiment, the second conductive layer may include a second central conductive layer overlapping the second central region and a second peripheral conductive layer overlapping the second peripheral region. In such an embodiment, the second central conductive layer may have a smaller thickness than the second peripheral conductive layer. In such an embodiment, the second central conductive layer may have a greater thickness than the first central conductive layer.

According to an embodiment of the disclosure, a third lower electrode among the lower electrodes may include a third central region and a third peripheral region surrounding the third central region, which are defined therein, and a thickness of the third central region of the third lower electrode may be equal to a thickness of the third peripheral region of the third lower electrode. In such an embodiment, the thickness of the third central region of the third lower electrode may be greater than the thickness of the second central region of the second lower electrode.

According to an embodiment of the disclosure, the third lower electrode may include a third protective layer, a third reflective layer, and a third conductive layer. In such an embodiment, the third reflective layer may be arranged on the third protective layer, and the third conductive layer may be arranged on the third reflective layer. In such an embodiment, the third conductive layer may include a third central conductive layer overlapping the third central region and a third peripheral conductive layer overlapping the third peripheral region. In such an embodiment, the third central conductive layer and the third peripheral conductive layer may have a same thickness as each other.

According to an embodiment of the disclosure, the third lower electrode may be disposed to correspond to a third light-emitting region among the plurality of light-emitting regions. In such an embodiment, the third light-emitting region may emit light in the red wavelength band.

According to an embodiment of the disclosure, the display element layer may include a plurality of light-emitting structures, which are stacked between the lower electrodes and the upper electrodes, and a charge generation layer. In such an embodiment, each of the plurality of light-emitting structures may include a hole functional layer and an electron functional layer arranged on either side of a light-emitting layer.

A method of manufacturing a display device according to an embodiment of the disclosure includes preparing a substrate, forming a circuit layer, forming preliminary lower electrodes, and forming lower electrodes. In such an embodiment, the circuit layer is formed on the substrate, and the preliminary lower electrodes may be formed on the circuit layer. In such an embodiment, a first preliminary lower electrode among the preliminary lower electrodes includes a first central region and a first peripheral region surrounding the first central region, which are defined therein. In such an embodiment, the forming lower electrodes includes etching a portion of the first preliminary lower electrode overlapping the first central region by use of a mask.

According to an embodiment of the disclosure, the etching preliminary lower electrodes may include forming a preliminary protective layer on the circuit layer, forming a preliminary reflective layer on the preliminary protective layer, forming a preliminary conductive layer on the preliminary reflective layer, and etching the preliminary protective layer, the preliminary reflective layer, and the preliminary conductive layer.

According to an embodiment of the disclosure, the first preliminary lower electrode may include a first preliminary protective layer, a first preliminary reflective layer, and a first preliminary conductive layer, which are defined by patterned portions of the preliminary protective layer, the preliminary reflective layer, and the preliminary conductive layer. In such an embodiment, the forming the lower electrodes may include etching a portion of the first preliminary conductive layer of the first preliminary lower electrode.

According to an embodiment of the disclosure, a second preliminary lower electrode among the preliminary lower electrodes may include a second central region and a second peripheral region surrounding the second central region, which are defined therein. In such an embodiment, the forming lower electrodes may include forming a photoresist on the lower electrodes, forming a first preliminary photoresist, forming a first intermediate lower electrode, forming a second preliminary photoresist, and forming a first lower electrode and a second lower electrode. In the forming a first preliminary photoresist, the mask may use a halftone mask to expose a portion of an upper surface of the first preliminary lower electrode overlapping the first central region and remove a portion of the photoresist such that the portion of the photoresist overlapping the second central region has a first thickness.

In the forming a first intermediate lower electrode, a portion of the first preliminary lower electrode may be etched. In the forming a second preliminary photoresist, a portion of the first preliminary photoresist may be removed to expose a portion of an upper surface of the second preliminary lower electrode overlapping the second central region. In the forming a first lower electrode and a second lower electrode, a portion of the first intermediate lower electrode and a portion of the second preliminary lower electrode may be etched.

According to an embodiment of the disclosure, a third preliminary lower electrode among the preliminary lower electrodes may include a third central region and a third peripheral region surrounding the third central region, which are defined therein. In such an embodiment, the forming the first preliminary photoresist may include not removing portions of the photoresist overlapping the first peripheral region, the second peripheral region, the third peripheral region, and the third central region.

According to an embodiment of the disclosure, the third preliminary lower electrode among the preliminary lower electrodes may include the third central region and the third peripheral region surrounding the third central region, which are defined therein. In the forming a second preliminary photoresist, the second preliminary photoresist may cover an upper surface of the third preliminary lower electrode.

According to an embodiment of the disclosure, the method may further include forming a pixel defining layer to cover a portion of the upper surface of the first lower electrode overlapping the first peripheral region and a portion of the upper surface of the first lower electrode overlapping the first central region and to cover a portion of the upper surface of the second lower electrode overlapping the second peripheral region and a portion of the upper surface of the second lower electrode overlapping the second central region.

A display device according to an embodiment of the disclosure includes a substrate, a circuit layer, first and second lower electrodes, a display element layer, and an upper electrode. In such an embodiment, a first light-emitting region and a second light-emitting region are defined on the substrate. In such an embodiment, the first light-emitting region emits light in the green wavelength band, and the second light-emitting region emits light in the blue wavelength band.

In such an embodiment, the circuit layer is disposed on the substrate and may include thin-film transistors. In such an embodiment, the first and second lower electrodes are disposed on the circuit layer and electrically connected to the thin-film transistors. In such an embodiment, the first and second lower electrodes are disposed to correspond, respectively, to the first and second light-emitting regions. In such an embodiment, the display element layer is disposed on the first and second lower electrodes. In such an embodiment, the upper electrode is disposed on the display element layer.

In such an embodiment, at least a portion of the first lower electrode has a thickness smaller than a thickness of at least a portion of the second lower electrode.

According to embodiments of the disclosure as described herein, by controlling the thickness of the lower electrodes differently for each light-emitting region, it is possible to optimize the optical distance for each light-emitting region and implement a display device with improved light efficiency.

### BRIEF DESCRIPTION OF THE DRAWINGS

These and/or other features of embodiments of the disclosure will become apparent and more readily appreciated from the following description of the embodiments, taken in conjunction with the accompanying drawings, in which:

FIG. 1 is a plan view illustrating a display device according to an embodiment of the disclosure;

FIG. 2 is a cross-sectional view taken along line I-I′ of FIG. 1;

FIG. 3A illustrates an enlarged view of the AA region shown in FIG. 2;

FIG. 3B illustrates an enlarged view of the BB region shown in FIG. 2;

FIG. 3C illustrates an enlarged view of the CC region shown in FIG. 2;

FIG. 4 is a graph illustrating the effects according to an embodiment of the disclosure; FIG. 5 is a cross-sectional illustrating another embodiment of the display device shown in FIG. 2;

FIG. 6 is a cross-sectional illustrating yet another embodiment of the display device shown in FIG. 2;

FIG. 7 is a flow diagram illustrating a method of manufacturing a display device according to an embodiment of the disclosure;

FIG. 8 is a flow diagram illustrating a method of manufacturing a display device according to an embodiment of the disclosure;

FIG. 9 is a flow diagram illustrating a method of manufacturing a display device according to an embodiment of the disclosure;

FIG. 10 is a diagram illustrating the processes of the method of manufacturing a display device as shown in FIGS. 7 and 8;

FIGS. 11A to 11E are diagrams illustrating the processes of the method of manufacturing a display device as shown in FIG. 9;

FIGS. 12 to 14 are diagrams illustrating the processes of the method of manufacturing a display device as shown in FIG. 7; and

FIGS. 15 and 16 are diagrams illustrating electronic devices to which the display device according to an embodiment of the disclosure is applied.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

When an element (or region, layer, portion, etc.) is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. On the other hand, if one element is described to be “directly disposed on,” “directly placed on,” “directly arranged on,” “directly connected to,” or “directly coupled to” another element, it shall be construed that there is no intervening element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the disclosure shall not be restricted to the thicknesses, ratios, dimensions, etc. illustrated in the drawings.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Moreover, relative terms, such as “below,” “under,” “beneath,” “lower,” “bottom,” “above,” “over,” “upper,” “top,” etc., may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The term “below” or “beneath”can therefore encompass an orientation of both above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an. ” “Or” means “and/or. ” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

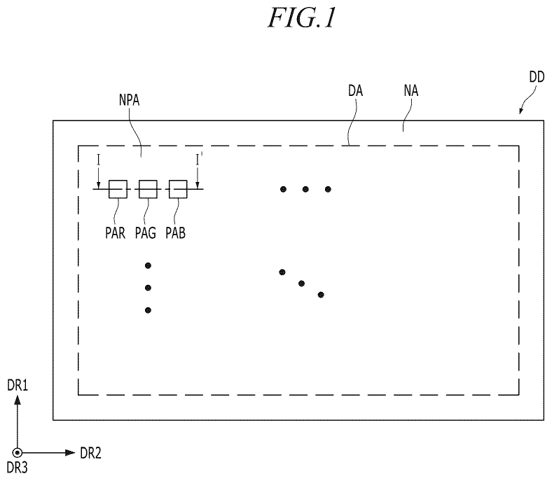

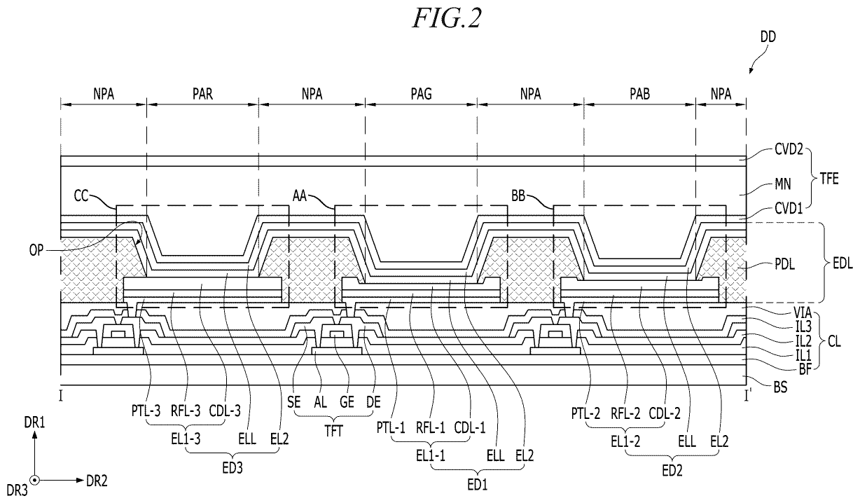

FIG. 1 is a plan view illustrating a display device according to an embodiment of the disclosure. Directions DR1, DR2, DR3 may be defined. A first direction DR1 and a second direction DR2 may be directions defined on a plane defined by a display surface of the display device DD shown in FIG. 1 and may intersect each other. A third direction DR3 may be the thickness direction of the display device DD, as defined in FIG. 2.

Referring to FIG. 1, the display device DD according to an embodiment of the disclosure may be an image display device and may have a display area DA and a peripheral area NA defined therein. The display area DA may be a region where images are displayed, while the peripheral area NA may be a region that surrounds the display area DA and in which images are not displayed. In some embodiments, the peripheral area NA may be omitted.

In an embodiment, as shown in FIG. 1, the display device DD may have a rectangular shape, with the peripheral area NA surrounding the display area DA in a plan view or when viewed in the third direction DR3. However, the planar shapes of the display area DA and the peripheral area NA are not limited to this and may be designed in various forms.

FIG. 2 is a cross-sectional view taken along line I-I′ of FIG. 1. Referring to FIGS. 1 and 2, the display device DD in an embodiment of the disclosure may have a plurality of light-emitting regions PAR, PAG, PAB and a non-light-emitting region NPA defined therein. The plurality of light-emitting regions PAR, PAG, PAB may be regions defined on a plane and may be similarly defined with respect to a substrate BS and its upper components, which will be described later. In an embodiment, the plurality of light-emitting regions PAR, PAG, PAB may be regions defined on the substrate BS, and the components disposed on the substrate in the plurality of light-emitting regions PAR, PAG, PAB may be disposed on the substrate to overlap the plurality of light-emitting regions PAR, PAG, PAB defined thereon in a plan view or when viewed in the third direction DR3.

The light-emitting regions PAR, PAG, PAB may be regions where images are displayed. The plurality of light-emitting regions PAR, PAG, PAB may include a first light-emitting region PAG, a second light-emitting region PAB, and a third light-emitting region PAR. In an embodiment of the disclosure, the first light-emitting region PAG may be a green light-emitting region configured to emit green light, and the second light-emitting region PAB may be a blue light-emitting region configured to emit blue light, while the third light-emitting region PAR may be a red light-emitting region configured to emit red light.

Each of the plurality of light-emitting regions PAR, PAG, PAB may have various shapes on a plane or in a plan view. In an embodiment, as shown in FIGS. 1 and 2, the light-emitting regions PAR, PAG, PAB may be rectangles, but this is only an example, and the shapes may be circular, elliptical, polygonal, etc. In an embodiment, as shown in FIGS. 1 and 2, the areas of the light-emitting regions PAR, PAG, PAB may have a same size as each other, but this is also an example, and the light-emitting regions PAR, PAG, PAB may have different sizes.

In an embodiment, the display device DD may include a substrate BS, a circuit layer CL, a light-emitting diode layer EDL, and an encapsulation layer TFE. The substrate BS may be an element that provides a base surface on which the circuit layer CL is disposed. The substrate BS may include materials such as glass, ceramic, metal, or polymer resin such as polyimide. However, the substrate BS is not limited to these materials and may be an inorganic layer, organic layer, or composite material, which may be monolayer or multilayers (i.e., may have a single layer structure or a multi-layer structure).

The circuit layer CL may be arranged on the substrate BS and may include thin-film transistors TFT, a first insulating layer IL1, a second insulating layer IL2, a third insulating layer IL3, and a via planarization layer VIA. In an embodiment, the circuit layer CL may further include a buffer layer BF. The thin-film transistors TFT may each include an active layer AL, which is a semiconductor pattern, a gate electrode GE, and a source electrode SE and a drain electrode DE electrically connected to the active layer AL.

The first insulating layer IL1 may be disposed on the substrate BS and may cover the active layer AL. The second insulating layer IL2 may be disposed on the first insulating layer IL1 and may cover the gate electrode GE. The third insulating layer IL3 may be disposed on the second insulating layer IL2 and may cover the source electrode SE and the drain electrode DE. Each of the first to third insulating layers IL1, IL2, IL3 may be an inorganic or organic layer.

The via planarization layer VIA may be disposed on the third insulating layer IL3 and may include organic film and/or inorganic film. The via planarization layer VIA may provide a planar surface, that is, may have a flat upper surface.

The buffer layer BF may be disposed between the substrate BS and the first insulating layer IL1 and may be configured to enhance an adhesive force of the semiconductor pattern disposed on the buffer layer BF. The buffer layer BF may be an inorganic layer including at least one inorganic material selected from silicon nitride, silicon oxide, and silicon oxynitride.

The light-emitting diode layer EDL may be disposed on the circuit layer CL and may include light-emitting diodes ED1, ED2, ED3 and a pixel defining layer PDL. The first light-emitting diode ED1 may correspond to the first light-emitting region PAG, and the second light-emitting diode ED2 may correspond to the second light-emitting region PAB, while the third light-emitting diode ED3 may correspond to the third light-emitting region PAR.

The light-emitting diodes ED1, ED2, ED3 may each include lower electrodes EL1-1, EL1-2, EL1-3 arranged to correspond to the plurality of light-emitting regions PAG, PAB, PAR, a display element layer ELL, and an upper electrode EL2. In an embodiment of the disclosure, the thin-film transistors TFT may be electrically connected, respectively, to the lower electrodes EL1-1, EL1-2, EL1-3 to receive electrical signals.

The lower electrodes EL1-1, EL1-2, EL1-3 may be arranged on the circuit layer CL and may serve (or function) as cathodes or anodes. In an embodiment, the lower electrodes EL1-1, EL1-2, EL1-3 may serve as anodes.

The first light-emitting diode ED1 may include a first lower electrode EL1-1, and the second light-emitting diode ED2 may include a second lower electrode EL1-2, while the third light-emitting diode ED3 may include a third lower electrode EL1-3.

The first lower electrode EL1-1 may include a first protective layer PTL-1, a first reflective layer RFL-1, and a first conductive layer CDL-1 that are sequentially stacked one on another. The second lower electrode EL1-2 may include a second protective layer PTL-2, a second reflective layer RFL-2, and a second conductive layer CDL-2 that are sequentially stacked one on another. The third lower electrode EL1-3 may include a third protective layer PTL-3, a third reflective layer RFL-3, and a third conductive layer CDL-3 that are sequentially stacked one on another.

The first through third protective layers PTL-1, PTL-2, PTL-3 may be arranged in (or directly on) a same layer as each other. The first through third protective layers PTL-1, PTL-2, PTL-3 may include at least one selected from conductive materials such as indium tin oxide (ITO), indium zinc oxide (IZO), zinc oxide (ZnO), indium tin zinc oxide (ITZO), etc.

In an embodiment, the first through third protective layers PTL-1, PTL-2, PTL-3 may effectively prevent the materials included in the first through third reflective layers RFL-1, RFL-2, RFL-3 from mixing with the materials included in the via planarization layer VIA disposed beneath the first through third protective layers PTL-1, PTL-2, PTL-3. In an embodiment, the first through third protective layers PTL-1, PTL-2, PTL-3 may be configured to protect the via planarization layer VIA disposed beneath the first through third protective layers PTL-1, PTL-2, PTL-3.

The first through third reflective layers RFL-1, RFL-2, RFL-3 may be arranged in (or directly on) a same layer as each other. The first through third reflective layers RFL-1, RFL-2, RFL-3 may include at least one selected from Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or any combination or compound thereof (e.g., a mixture of Ag and Mg).

The first through third conductive layers CDL-1, CDL-2, CDL-3 may be arranged in (or directly on) a same layer as each other. The first through third conductive layers CDL-1, CDL-2, CDL-3 may include at least one selected from conductive oxides such as ITO, IZO, ZnO, or ITZO. In an embodiment of the disclosure, the first through third conductive layers CDL-1, CDL-2, CDL-3 may include ITO.

In an embodiment of the disclosure, at least one selected from the first through third lower electrodes EL1-1, EL1-2, EL1-3 may have a central region and a peripheral region defined therein, and at least one selected from the first through third lower electrodes EL1-1, EL1-2, EL1-3 may have different thicknesses in the central region and the peripheral region, which will be described later in greater detail. That is, a thickness of a portion of the at least one selected from the first through third lower electrodes EL1-1, EL1-2, EL1-3 in the central region is different from a thickness of a portion thereof in the peripheral region.

The display element layer ELL may be disposed on the lower electrodes EL1-1, EL1-2, EL1-3. in an embodiment, the display element layer ELL may be disposed on the lower electrodes EL1-1, EL1-2, EL1-3 and on an inner surface of the pixel defining layer PDL that defines an opening OP.

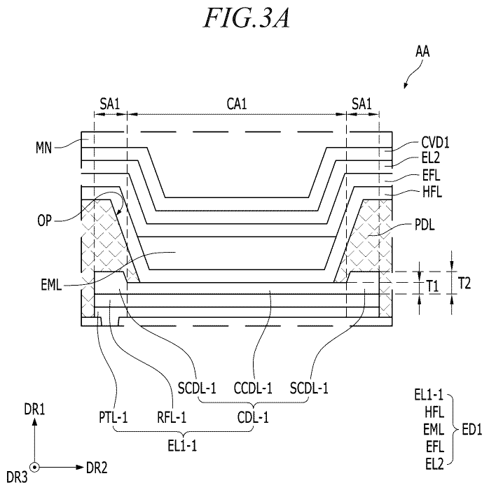

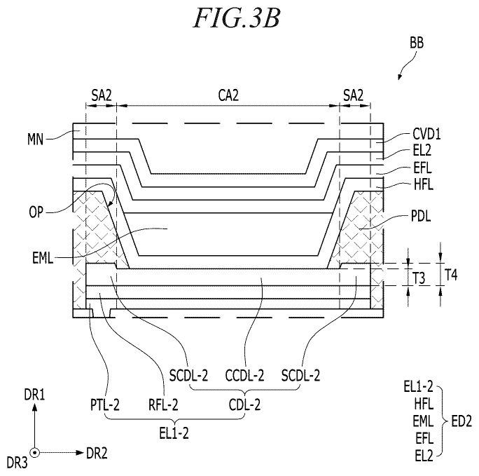

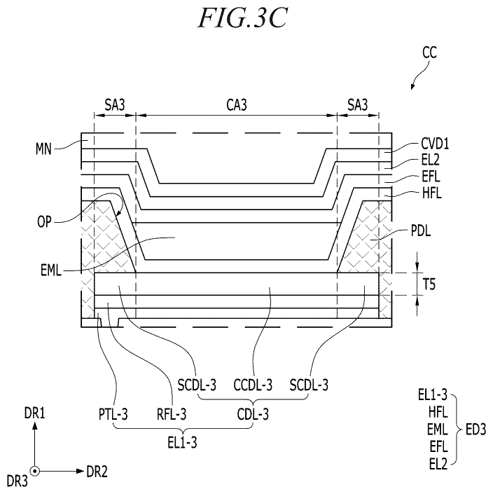

Although not illustrated in FIG. 2, the display element layer ELL may include a light-emitting layer (not shown) disposed between the lower electrodes EL1-1, EL1-2, EL1-3 and the upper electrode EL2. The display element layer ELL and the pixel defining layer PDL will be described in detail with reference to FIGS. 3a to 3c.

The upper electrode EL2 may be disposed on the display element layer ELL and may face the lower electrodes EL1-1, EL1-2, EL1-3. The upper electrode EL2 may be a common electrode having an integrated shape extending from the light-emitting regions PAR, PAG, PAB to the non-light-emitting region NPA.

The upper electrode EL2 may be a cathode or an anode. In an embodiment, the upper electrode EL2 may be a cathode. The upper electrode EL2 may include at least one selected from alloys, metals, conductive compounds, or any combination thereof with a low work function. In an embodiment, for example, the upper electrode EL2 may include at least one selected from lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The upper electrode EL2 may be a transparent electrode, a semi-transparent electrode, or a reflective electrode.

Although not shown in the drawings, the upper electrode EL2 may be connected to an auxiliary electrode (not shown). In such an embodiment where the upper electrode EL2 is connected to the auxiliary electrode, the resistance of the upper electrode EL2 may be reduced.

In an embodiment, the upper electrode EL2 may have a single-layer structure or a multi-layer structure. In an embodiment, the light-emitting diodes ED1, ED2, ED3 may form a microcavity structure, which will be described later in greater detail.

The encapsulation layer TFE may be configured to protect the light-emitting diode layer EDL from external oxygen or moisture by sealing the light-emitting diode layer EDL. The encapsulation layer TFE may include a first inorganic layer CVD1, an organic layer MN, and a second inorganic layer CVD2. Although FIG. 2 shows an embodiment where the encapsulation layer TFE includes two inorganic layers and one organic layer, the disclosure is not limited to what is illustrated herein. In another embodiment, for example, the encapsulation layer TFE may include three inorganic layers and two organic layers, in which case the inorganic and organic layers may be alternately stacked.

FIG. 3A is an enlarged view of the AA region shown in FIG. 2, and FIG. 3B is an enlarged view of the BB region shown in FIG. 2, while FIG. 3C is an enlarged view of the CC region shown in FIG. 2. The AA region of FIG. 2 corresponds to the first light-emitting region PAG and its surrounding area, and the BB region corresponds to the second light-emitting region PAB and its surrounding area, while the CC region corresponds to the third light-emitting region PAR and its surrounding area. Referring to FIGS. 2, 3A, 3B, and 3C, the first through third lower electrodes EL1-1, EL1-2, EL1-3, the display element layer ELL, and the pixel defining layer PDL will hereinafter be described in detail.

Referring to FIG. 3A, the first lower electrode EL1-1, among the lower electrodes EL1-1, EL1-2, EL1-3, may have a first central region CA1 and a first peripheral region SA1 surrounding the first central region CA1 defined therein. In the third direction DR3, the thickness of the first lower electrode EL1-1 in the first central region CA1 may be smaller than the thickness of the first lower electrode EL1-1 in the first peripheral region SA1.

In an embodiment, the first lower electrode EL1-1 may include a first reflective layer RFL-1 disposed on a first protective layer PTL-1 in the third direction DR3 and a first conductive layer CDL-1 disposed on the first reflective layer RFL-1. The first conductive layer CDL-1 may include a first central conductive layer CCDL-1 overlapping the first central region CA1 and a first peripheral conductive layer SCDL-1 overlapping the first peripheral region SA1. A first thickness T1, which is a thickness of the first central conductive layer CCDL-1, may be smaller than a second thickness T2, which is a thickness of the first peripheral conductive layer SCDL-1. In an embodiment, the first conductive layer CDL-1 may include, but not limited to, indium tin oxide (ITO).

Referring to FIG. 3B, the second lower electrode EL1-2, among the lower electrodes EL1-1, EL1-2, and EL1-3, may have a second central region CA2 and a second peripheral region SA2 surrounding the second central region CA2 defined therein. In the third direction DR3, the thickness of the second lower electrode EL1-2 in the second central region CA2 may be smaller than the thickness of the second lower electrode EL1-2 in the second peripheral region SA2.

In an embodiment, the second lower electrode EL1-2 may include a second reflective layer RFL-2 disposed on a second protective layer PTL-2 in the third direction DR3 and a second conductive layer CDL-2 disposed on the second reflective layer RFL-2. The second conductive layer CDL-2 may include a second central conductive layer CCDL-2 overlapping the second central region CA2 and a second peripheral conductive layer SCDL-2 overlapping the second peripheral region SA2. In the third direction DR3, a third thickness T3, which is a thickness of the second central conductive layer CCDL-2, may be smaller than a fourth thickness T4, which is a thickness of the second peripheral conductive layer SCDL-2.

In an embodiment of the disclosure, the third thickness T3 of the second central conductive layer CCDL-2 may be greater than the first thickness T1 of the first central conductive layer CCDL-1 in the third direction DR3. Referring to FIGS. 3A and 3B, the first lower electrode EL1-1 overlapping the first peripheral region SA1 may have a same thickness in the third direction DR3 as the second lower electrode EL1-2 overlapping the second peripheral region SA2. The second thickness T2 of the first peripheral conductive layer SCDL-1 may be equal to the fourth thickness T4 of the second peripheral conductive layer SCDL-2 in the third direction DR3.

Referring to FIG. 3C, the third lower electrode EL1-3, among the lower electrodes EL1-1, EL1-2, EL1-3, may have a third central region CA3 and a third peripheral region SA3 surrounding the third central region CA3 defined therein. In the third direction DR3, the thickness of the third lower electrode EL1-3 in the third central region CA3 may be substantially the same as the thickness of the third lower electrode EL1-3 in the third peripheral region SA3. In an embodiment of the disclosure, the third lower electrode EL1-3 may include a third reflective layer RFL-3 disposed on a third protective layer PTL-3 in the third direction DR3 and a third conductive layer CDL-3 disposed on the third reflective layer RFL-3. The third conductive layer CDL-3 may include a third central conductive layer CCDL-3 overlapping the third central region CA3 and a third peripheral conductive layer SCDL-3 overlapping the third peripheral region SA3. The third central conductive layer CCDL-3 and the third peripheral conductive layer SCDL-3 may have a same thickness, e.g., a fifth thickness T5, in the third direction DR3.

Referring to FIGS. 3B and 3C, in the third direction DR3, the thickness of the third lower electrode EL1-3 in the third central region CA3 may be greater than the thickness of the second lower electrode EL1-2 in the second central region CA2 and the thickness (not shown) of the first lower electrode EL1-1 in the first central region CA1. Referring to FIGS. 3A, 3B, and 3C, the fifth thickness T5 of the third peripheral conductive layer SCDL-3 may be the same as the second thickness T2 of the first peripheral conductive layer SCDL-1 and the fourth thickness T4 of the second peripheral conductive layer SCDL-2 in the third direction DR3.

In an embodiment, the first thickness T1 of the first central conductive layer CCDL-1 may be in a range, but not limited to, from about 200 angstrom (Å) to about 400 Å, and the third thickness T3 of the second central conductive layer CCDL-2 may be in a range, but not limited to, from about 500 Å to about 700 Å, while the fifth thickness T5 of the third central conductive layer CCDL-3 may be in a range, but not limited to, from about 700 Å to about 900 Å.

The pixel defining layer PDL may be disposed between the circuit layer CL and the display element layer ELL. The pixel defining layer PDL may be provided with an opening OP defined therein to expose at least a portion of the top surfaces of the first through third lower electrodes EL1-1, EL1-2, EL1-3.

The opening OP of the pixel defining layer PDL exposing at least a portion of the first lower electrode EL1-1 may correspond to the first light-emitting region PAG (see FIG. 2) defined therein, and the opening OP exposing at least a portion of the second lower electrode EL1-2 may correspond to the second light-emitting region PAB (see FIG. 2) defined therein, while the opening OP exposing at least a portion of the third lower electrode EL1-3 may correspond to the third light-emitting region PAR (see FIG. 2) defined therein.

In an embodiment, the pixel defining layer PDL may cover the first peripheral conductive layer SCDL-1 and a portion of the first central conductive layer CCDL-1 connected to the first peripheral conductive layer SCDL-1. In an embodiment, the pixel defining layer PDL may further cover the second peripheral conductive layer SCDL-2 and a portion of the second central conductive layer CCDL-2 connected to the second peripheral conductive layer SCDL-2, as well as the third peripheral conductive layer SCDL-3 and a portion of the third central conductive layer CCDL-3 connected to the third peripheral conductive layer SCDL-3.

At a boundary between the first central conductive layer CCDL-1 and the first peripheral conductive layer SCDL-1, and at a boundary between the second central conductive layer CCDL-2 and the second peripheral conductive layer SCDL-2, differences in thickness may make it difficult to control electrons or holes based on the voltage applied to the first lower electrode EL1-1 and the second lower electrode EL1-2.

In an embodiment of the disclosure, the pixel defining layer PDL may not only completely cover the first peripheral conductive layer SCDL-1 and the second peripheral conductive layer SCDL-2 but also cover portions of the first central conductive layer CCDL-1 and the second central conductive layer CCDL-2 connected, respectively, to the first peripheral conductive layer SCDL-1 and the second peripheral conductive layer SCDL-2. Accordingly, it is possible to form the first and second light-emitting regions PAG, PAB (see FIG. 2) in areas narrower than the first and second central regions CA1, CA2, thereby improving display quality. The pixel defining layer PDL may be an insulating layer including polymer resin material and/or inorganic material and may be formed as a single layer or multiple layers. However, the disclosure is not limited to these configurations.

Although the display element layer ELL is illustrated as a single layer in the embodiment of FIG. 2, the display element layer ELL in the embodiments shown in FIGS. 3A, 3B, and 3C may include a hole functional layer HFL, a light-emitting layer EML, and an electron functional layer EFL, with the lower electrodes EL1-1, EL1-2, EL1-3 and the upper electrode EL2 stacked therebetween.

The light-emitting layer EML may include a polymer or small-molecule organic material configured to emit a predetermined color. Although not illustrated, the hole functional layer HFL may include a hole injection layer (not shown) and a hole transport layer (not shown), and the electron functional layer EFL may include an electron transport layer (not shown) and an electron injection layer (not shown).

Referring to FIGS. 3A, 3B, and 3C, the light-emitting diodes ED1, ED2, ED3 may form or define a microcavity structure. The first through third lower electrodes EL1-1, EL1-2, EL1-3 may be reflective electrodes. In an embodiment, light may be reflected by the first through third reflective layers RFL-1, RFL-2, RFL-3 of the first through third lower electrodes EL1-1, EL1-2, EL1-3. Accordingly, the display device DD may be configured in a way such that light emitted from the light-emitting layer EML passes through the upper electrode EL2 and is emitted to the outside.

Light emitted from the light-emitting layer EML may pass through the upper electrode EL2 or be reflected by the first through third lower electrodes EL1-1, EL1-2, EL1-3 before being emitted to an outside. Here, light having passed through the upper electrode EL2 and light reflected by the first through third lower electrodes EL1-1, EL1-2, EL1-3 may undergo constructive interference, resulting in resonance. Therefore, to enhance the light extraction efficiency of the light emitted from the light-emitting layer EML, the distance between the first through third lower electrodes EL1-1, EL1-2, EL1-3 and the upper electrode EL2 may be individually configured to satisfy the conditions for constructive interference.

In an embodiment of the disclosure, by controlling the thickness of the first central conductive layer CCDL-1 in the first light-emitting region PAG, the second central conductive layer CCDL-2 in the second light-emitting region PAB, and the third central conductive layer CCDL-3 in the third light-emitting region PAR, it becomes possible to adjust the resonance distance of light emitted from the light-emitting layer EML.

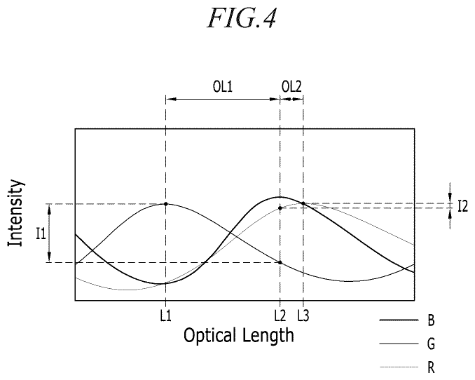

FIG. 4 is a graph illustrating the intensity of light emitted from red (R), green (G), and blue (B) light-emitting regions as a function of the optical length of the red (R), green (G), and blue (B) light-emitting regions. The optical length may be defined as the distance from the anode to the cathode.

In a comparative example of a display device, the lower electrodes of the red, green, and blue light-emitting regions all have a same thickness. In the comparative example, the red, green, and blue light-emitting regions have different resonance distances but may conform to a single resonance distance optimized for only one color, leading to reduced light efficiency.

According to an embodiment of the disclosure, the lower electrodes of the red, green, and blue light-emitting regions have different thicknesses from each other, enabling differential implementation of the resonance distances.

Referring to FIG. 4, while an optimal resonance is achieved with a focus on blue (B) in the comparative example, it can be inferred in an embodiment of the disclosure that the light intensity is varied by adjusting the thickness of the lower electrodes EL1-1, EL1-2, EL1-3 to individually adjust the optical length of the green (G), blue (B), and red (R) light-emitting regions.

In an embodiment, the green, blue, and red light-emitting regions may each have a maximum light intensity at respective peak optical lengths L1, L2, L3. The first peak optical length L1 may be shorter than the second peak optical length L2 by a first optical length difference OL1.

In an embodiment, the green (G) light-emitting region can achieve a maximum light efficiency by adjusting the first thickness T1 of the first central conductive layer CCDL-1 (see FIG. 3A) to provide the first peak optical length L1. The light efficiency of the green (G) light-emitting region may be improved by a first intensity difference I1 compared to the comparative example.

The third peak optical length L3 may be shorter than the second peak optical length L2 by a second optical length difference OL2.

The blue (B) light-emitting region can achieve a maximum light efficiency by adjusting the fifth thickness T5 of the third central conductive layer CCDL-3 (see FIG. 3C) to provide the second peak optical length L2.

The red (R) light-emitting region can achieve a maximum light efficiency by adjusting the third thickness T3 of the second central conductive layer CCDL-2 (see FIG. 3B) to provide the third peak optical length L3. The light efficiency of the red (R) light-emitting region may be improved by a second intensity difference I2 compared to the comparative example.

FIG. 5 is a cross-sectional view illustrating a portion of a display device DD-1 according to another embodiment of the disclosure. The embodiment of the display device DD-1, shown in FIG. 5, will be described primarily focusing on differences from the embodiment of the display device DD described above with reference to FIGS. 2, 3A, 3B, and 3C. Components not explicitly described here may refer to the descriptions of the same or like components provided above with reference to FIGS. 2, 3A, 3B, and 3C.

Referring to FIG. 5, in an embodiment of the disclosure, the display element layer ELL (see FIG. 2) may include a plurality of light-emitting structures OL1, OL1n-1, OL1n, and charge generation layers CGL1, CGL1n-1, which are stacked between the lower electrodes EL1-1, EL1-2, EL1-3 and the upper electrode EL2.

Each of the plurality of light-emitting structures OL1, OL1n-1, OL1n may include a tandem structure of light-emitting diodes including a hole functional layer (not shown) and an electron functional layer (not shown) with light-emitting layers (not shown) arranged therebetween.

Hereinafter, for convenience of description, the display device DD-1 will be mainly described focusing on the first light-emitting diode ED1 among the plurality of light-emitting diodes ED1, ED2, ED3. In an embodiment of the disclosure, the plurality of light-emitting diodes ED1, ED2, ED3 may have a substantially same structure as each other. Accordingly, it would be understood that the description for the first light-emitting diode ED1 can be identically applied to the second light-emitting diode ED2 and/or the third light-emitting diode ED3. The first light-emitting diode ED1 may include n light-emitting structures OL1, OL1n-1, OL1n and (n-1) charge generation layers CGL1, CGL1n-1 stacked between the first lower electrode EL1-1 and the upper electrode EL2. Here, n may be a natural number.

Each of the light-emitting structures OL1, OLn-1, OLn may include a hole functional layer (not shown) and an electron functional layer (not shown), with light-emitting layers (not shown) disposed therebetween. That is, the first light-emitting diode ED1 included in the display device DD-1 according to an embodiment may have a tandem structure of light-emitting diode including a plurality of light-emitting layers (not shown).

The charge generation layers CGL1, CGLn-1 may be disposed between neighboring light-emitting structures OL1, OLn-1, OLn. The charge generation layers CGL1, CGLn-1 may include a p-type charge generation layer and/or an n-type charge generation layer.

FIG. 5 illustrates an embodiment of the display device DD-1 including three light-emitting structures OL1, OL1n-1, OL1n and two charge generation layers CGL1, CGL1n-1, where n equals 2. In another embodiment, the (n-1)-th light-emitting structure OL1n-1 and the (n-1)-th charge generation layer CGL1n-1 may be omitted, and the n-th light-emitting structure OL1n may be in direct contact with the first charge generation layer CGL1, where n equals 1. In another embodiment, light-emitting structures and charge generation layers may be sequentially added between the first charge generation layer CGL1 and the (n-1)-th light-emitting structure OL1n-1, where n is 3 or greater.

In an embodiment, the light-emitting structures OL1, OL1n-1, OL1n included in the first light-emitting diode ED1 may emit light in a same wavelength range. However, the disclosure is not limited thereto, and at least one of the light-emitting structures OL1, OL1n-1, OL1n included in the first light-emitting diode ED1 may emit light of different wavelengths.

In an embodiment shown in FIG. 5, as described above, the light-emitting diodes ED1, ED2, ED3 may light in green, blue, and red wavelength bands, respectively, but the disclosure is not limited thereto. In an embodiment, the light-emitting diodes ED1, ED2, and ED3 may have a same structure as each other as shown in FIG. 5, but the disclosure is not limited thereto. Some (e.g., at least one) of the light-emitting diodes ED1, ED2, ED3 may include k light-emitting structures (k being a natural number), while others may include m light-emitting structures (m being a different natural number from k).

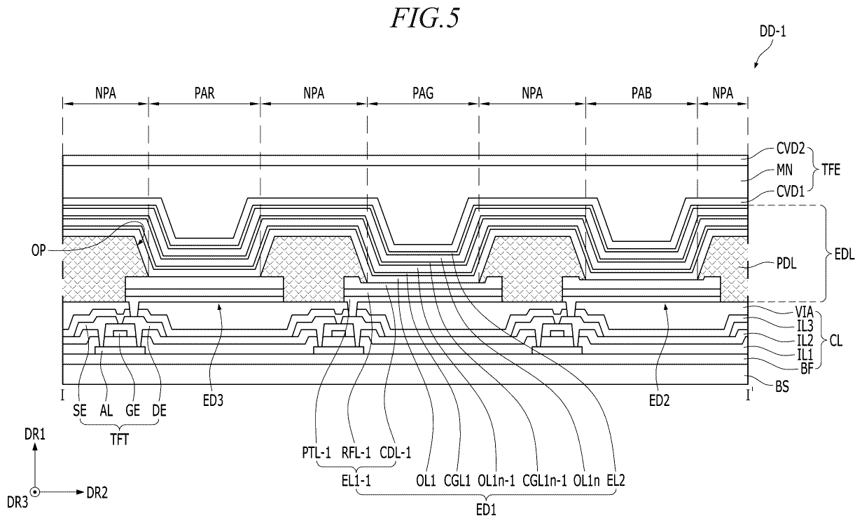

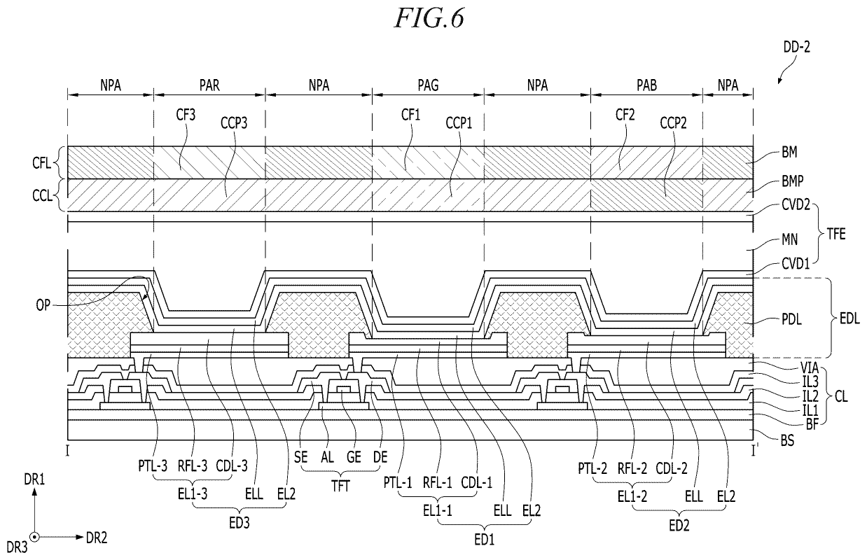

FIG. 6 is a cross-sectional view illustrating a portion of a display device DD-2 according to another embodiment of the disclosure. The embodiments of the display device DD-2 shown in FIG. 6, will be described primarily focusing on differences from the embodiment of the display device DD described with reference to FIGS. 2, 3A, 3B, and 3C. Components not explicitly described here may refer to the descriptions of the same or like components provided above with reference to FIG. 2.

An embodiment of the display device DD-2 may include a light control layer CCL and a color filter layer CFL disposed on the encapsulation layer TFE.

The light control layer CCL may include a plurality of light control portions CCP1, CCP2, CCP3. In an embodiment, as shown in FIG. 6, the light control portions CCP1, CCP2, CCP3 may be spaced apart from each other, with dividing patterns BMP disposed therebetween. However, the disclosure is not limited thereto, and in other embodiments, the edges of the light control portions may overlap each other, and the edges of the light control portions may overlap the dividing patterns.

The light control layer CCL may include first through third light control portions CCP1-CCP3 overlapping, respectively, the first through third light-emitting diodes ED1-ED3.

At least one of the first through third light control portions CCP1-CCP3 may change the wavelength of incident light (e.g., blue light) to emit light of a different color (e.g., red light or green light). In such an embodiment, at least one of the first through third light control portions CCP1-CCP3 may transmit incident light (e.g., blue light) without changing its wavelength.

At least one of the first through third light control portions CCP1-CCP3 may include a light converter, such as quantum dots or phosphors. The light converter may be configured to convert the wavelength of received light and emit the converted light. The first through third light control portions CCP1-CCP3 may also include a scatterer and a base resin configured for dispersing the scatterer.

The light control layer CCL may further include a barrier layer (not shown) configured to effectively prevent the penetration of moisture and/or oxygen.

The color filter layer CFL may be disposed on the light control layer CCL. The color filter layer CFL may include a plurality of color filters CF1, CF2, CF3. In an embodiment, as shown in FIG. 6, the color filters CF1, CF2, CF3 may be spaced apart from each other, with a light-blocking portion BM disposed therebetween. However, the disclosure is not limited thereto, and in other embodiments, the edges of the color filters may overlap each other, and the edges of the color filters may overlap the light-blocking portion.

The color filter layer CFL may include first through third color filters CF1-CF3 overlapping, respectively, the first through third light-emitting diodes ED1-ED3.

The first through third color filters CF1-CF3 may be configured to selectively transmit light of specific colors. However, the disclosure is not limited thereto, and at least one of the first through third color filters CF1-CF3 may be transparent or semi-transparent.

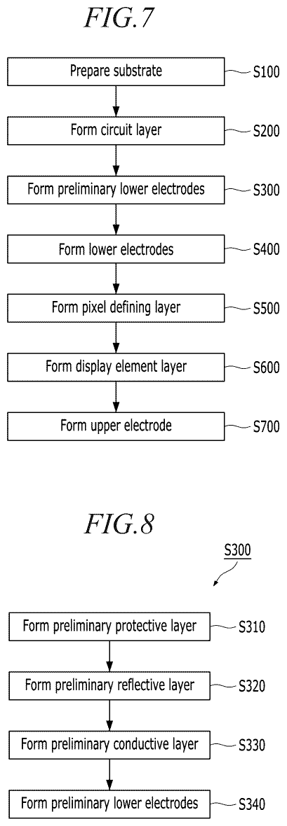

FIG. 7 is a flow diagram illustrating a method of manufacturing a display device according to an embodiment of the disclosure. Hereinafter, the descriptions of the elements of the display device DD described with reference to FIGS. 2, 3A, 3B, and 3C are identically applicable to the same or like elements formed by the manufacturing method, as denoted by the same reference numerals/symbols.

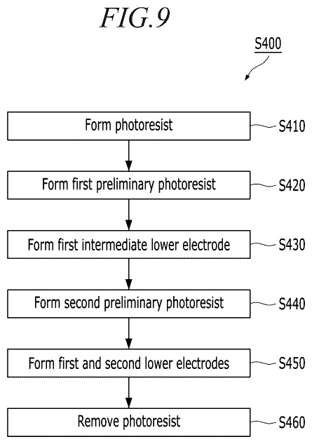

FIG. 8 is a flow diagram illustrating a method of manufacturing a display device according to an embodiment of the disclosure. FIG. 9 is a flow diagram illustrating a method of manufacturing a display device according to an embodiment of the disclosure.

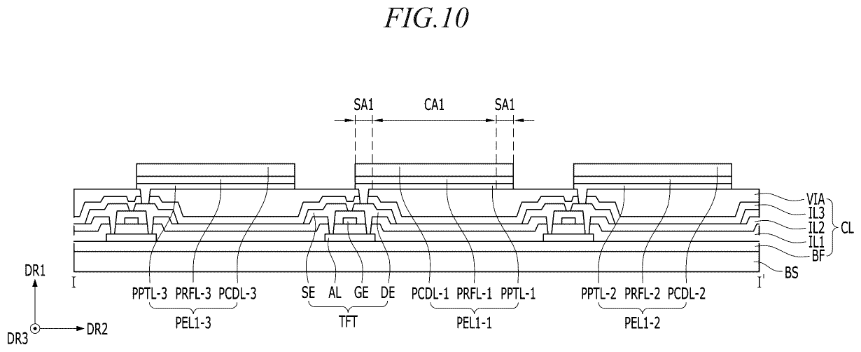

FIGS. 10, 11A through 11E, and 12 through 14 are cross-sectional views corresponding to some of the processes in the method of manufacturing a display device according to an embodiment of the disclosure.

Referring to FIG. 7, a method of manufacturing a display device according to an embodiment of the disclosure may include: preparing a substrate (S100); forming (or providing) a circuit layer on the substrate (S200); forming preliminary lower electrodes on the circuit layer (S300); forming lower electrodes by etching a portion of a first preliminary lower electrode overlapping a first central region using a mask (S400); forming a pixel defining layer (S500); forming a display element layer (S600); and forming an upper electrode (S700).

Referring to FIGS. 7 and 10, in the process of preparing the substrate (S100), the substrate BS may be prepared. In the process of forming the circuit layer (S200), the circuit layer CL may be formed (or provided) on the substrate BS. The circuit layer CL may include a transistor TFT, a buffer layer BF, a first insulating layer IL1, a second insulating layer IL2, a third insulating layer IL3, and a via planarization layer VIA.

Referring to FIG. 8, the process of forming preliminary the lower electrodes (S300) may include: forming a preliminary protective layer (S310); forming a preliminary reflective layer (S320); forming a preliminary conductive layer (S330); and forming preliminary lower electrodes (S340).

Referring to FIGS. 8 and 10, in the process of forming the preliminary lower electrodes (S300), a preliminary protective layer (not shown) may be formed on the circuit layer CL. In an embodiment, for example, the preliminary protective layer (not shown) may be formed using an open mask.

Subsequently, the preliminary reflective layer (not shown) may be formed on the preliminary protective layer (not shown). Then, the preliminary conductive layer (not shown) may be formed on the preliminary reflective layer (not shown). The preliminary protective layer, preliminary reflective layer, and preliminary conductive layer (all not shown) may be collectively formed by sputtering deposition.

Subsequently, the preliminary protective layer, preliminary reflective layer, and preliminary conductive layer (all not shown) may be etched.

Referring to FIG. 10, by etching the preliminary protective layer, preliminary reflective layer, and preliminary conductive layer (all not shown), a first preliminary lower electrode PEL1-1, a second preliminary lower electrode PEL1-2, and a third preliminary lower electrode PEL1-3 may be formed.

The first preliminary lower electrode PEL1-1 may include a first preliminary protective layer PPTL-1, a first preliminary reflective layer PRFL-1, and a first preliminary conductive layer PCDL-1 that are patterned and sequentially stacked.

The second preliminary lower electrode PEL1-2 may include a second preliminary protective layer PPTL-2, a second preliminary reflective layer PRFL-2, and a second preliminary conductive layer PCDL-2 that are patterned and sequentially stacked.

The third preliminary lower electrode PEL1-3 may include a third preliminary protective layer PPTL-3, a third preliminary reflective layer PRFL-3, and a third preliminary conductive layer PCDL-3 that are patterned and sequentially stacked.

Referring to FIG. 9, the process of forming the lower electrodes (S400) may include: forming a photoresist (S410), forming a first preliminary photoresist (S420), forming a first intermediate lower electrode (S430), forming a second preliminary photoresist (S440), forming first and second lower electrodes (S450), and removing the photoresist (S460).

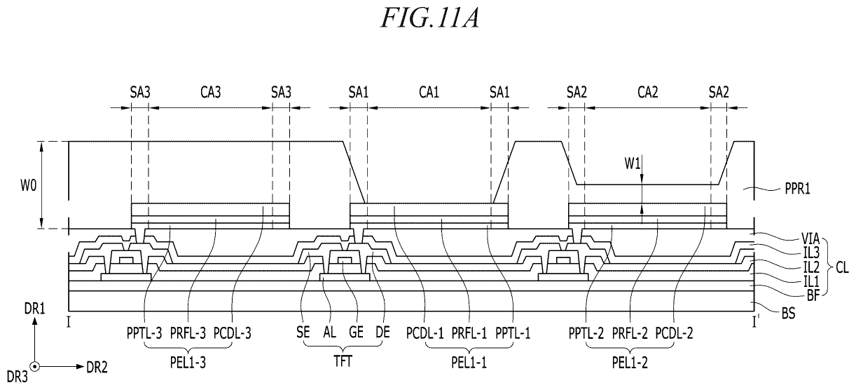

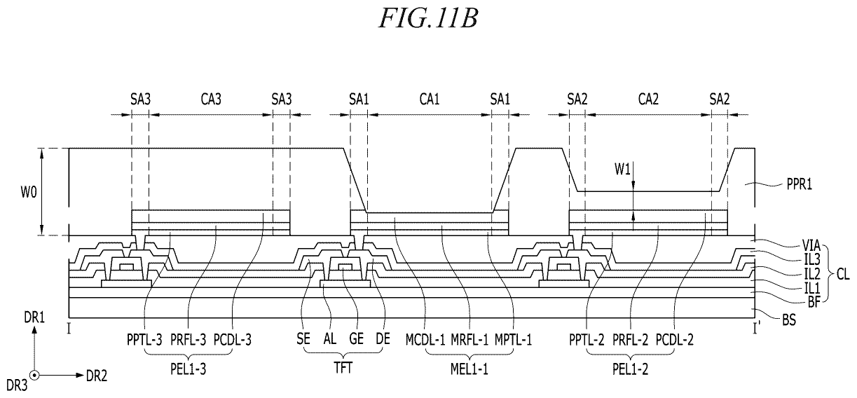

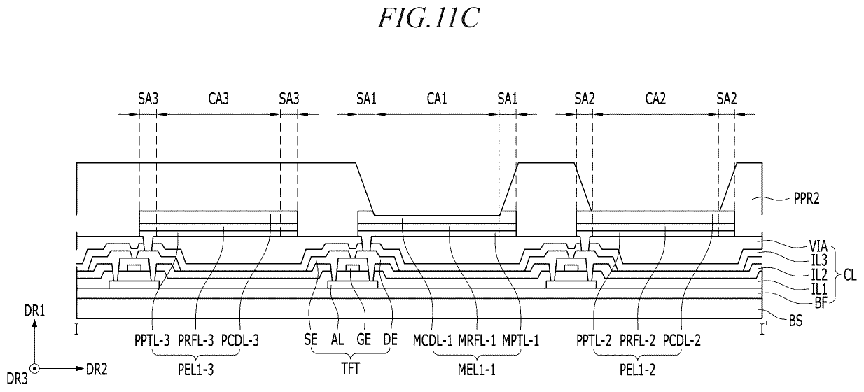

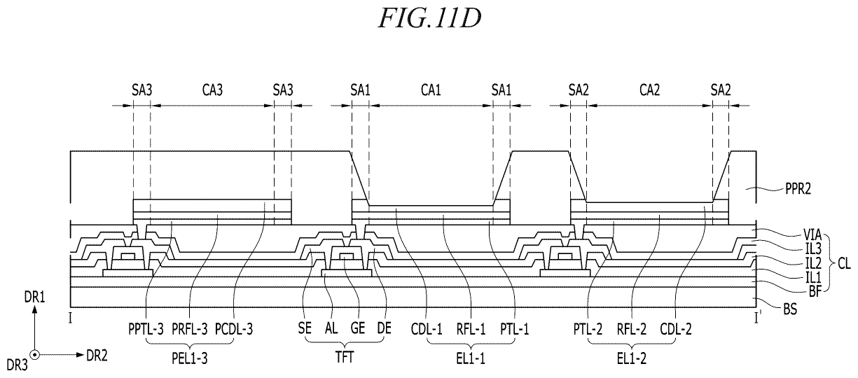

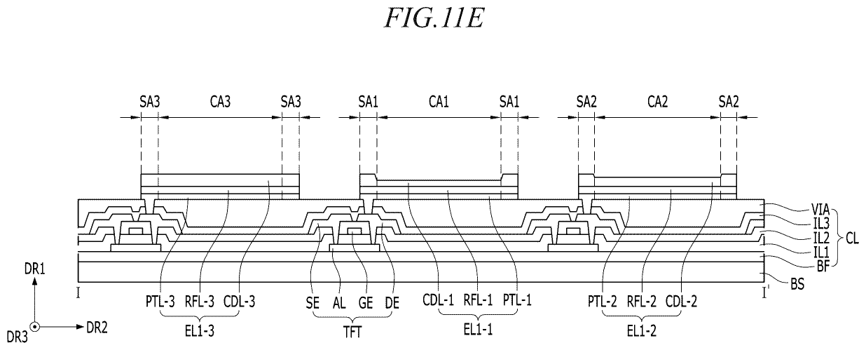

Referring to FIGS. 9 and 11A, in the process of forming the photoresist (S410), a photoresist (not shown) may be formed on the preliminary lower electrodes PEL1-1, PEL1-2, PEL1-3.

The first preliminary lower electrode PEL1-1 may include a first central region CA1 and a first peripheral region SA1 surrounding the first central region CA1, which are defined therein. The second preliminary lower electrode PEL1-2 may include a second central region CA2 and a second peripheral region SA2 surrounding the second central region CA2, which are defined therein. The third preliminary lower electrode PEL1-3 may include a third central region CA3 and a third peripheral region SA3 surrounding the third central region CA3, which are defined therein.

In the process of forming the first preliminary photoresist (S420), the first preliminary photoresist PPR1 may be formed.

The first preliminary photoresist PPR1 may be configured to expose the top surface of the first preliminary lower electrode PEL1-1 in the first central region CA1 and may have a first thickness W1 in the second central region CA2.

In an embodiment, for example, the first preliminary photoresist PPR1 may be formed by using a halftone mask to remove a portion of a photoresist having a thickness W0.

In the process of forming a first preliminary photoresist (S420), the portion of the photoresist overlapping the first peripheral region SA1, the second peripheral region SA2, the third peripheral region SA3, and the third central region CA3 may remain unremoved.

Referring to FIGS. 9 and 11B, in the process of forming the first intermediate lower electrode (S430), a portion of the first preliminary lower electrode PEL1-1 may be etched to form a first intermediate lower electrode MEL1-1. In an embodiment of the disclosure, for example, the process of forming the first intermediate lower electrode (S430) may be performed through a dry etching process or a wet etching process.

In an embodiment, in the process of forming the first intermediate lower electrode (S430), a portion of the first preliminary conductive layer PCDL1-1 exposed by the first preliminary photoresist PPR1 may be etched.

The first intermediate lower electrode MEL1-1 may include a first intermediate protective layer MPTL-1, a first intermediate reflective layer MRFL-1, and a first intermediate conductive layer MCDL-1.

Referring to FIGS. 9 and 11C, in the process of forming the second preliminary photoresist (S440), the second preliminary photoresist PPR2 may be formed. The second preliminary photoresist PPR2 may be configured to expose a portion of the top surface of the first intermediate lower electrode MEL1-1 overlapping the first central region CA1 and a portion of the top surface of the second preliminary lower electrode PEL1-2 overlapping the second central region CA2. In an embodiment, the second preliminary photoresist PPR2 may cover the top surface of the third preliminary lower electrode PEL1-3.

In an embodiment of the disclosure, the process of forming the second preliminary photoresist (S440) may be performed through an ashing process. In an embodiment of the disclosure, a portion of the top surface of the first intermediate lower electrode MEL1-1 may be etched when, but not limited to, the second preliminary photoresist PPR2 is formed by removing a portion of the first preliminary photoresist PPR1.

Referring to FIGS. 9 and 11D, in the process of forming the first and second lower electrodes (S450), the first lower electrode EL1-1 and the second lower electrode EL1-2 may be formed.

The first lower electrode EL1-1 may be formed by etching a portion of the first intermediate lower electrode MEL1-1. In an embodiment, in the process of forming first and second lower electrodes (S450), a portion of the first intermediate conductive layer MCDL-1 exposed by the second preliminary photoresist PPR2 may be etched. The first lower electrode EL1-1 may include a first protective layer PTL-1, a first reflective layer RFL-1, and a first conductive layer CDL-1.

The second lower electrode EL1-2 may be formed by etching a portion of the second preliminary lower electrode PEL1-2. In an embodiment, in the process of forming first and second lower electrodes (S450), a portion of the second preliminary conductive layer PCDL-2 exposed by the second preliminary photoresist PPR2 may be etched. The second lower electrode EL1-2 may include a second protective layer PTL-2, a second reflective layer RFL-2, and a second conductive layer CDL-2.

In an embodiment of the disclosure, the process of forming the first and second lower electrodes (S450) may be performed through a dry etching process or a wet etching process. After performing the etching process, a portion of the first lower electrode EL1-1 overlapping the first central region CA1 may have a smaller thickness than another portion of the first lower electrode EL1-1 overlapping the first peripheral region SA1, and a portion of the second lower electrode EL1-2 overlapping the second central region CA2 may have a smaller thickness than another portion of the second lower electrode EL1-2 overlapping the second peripheral region SA2.

Referring to FIGS. 9 and 11E, in the process of removing the photoresist (S460), the second preliminary photoresist PPR2 covering the first peripheral region SA1, the second peripheral region SA2, the third central region CA3, and the third peripheral region SA3 may be entirely removed, thereby fully exposing the third preliminary lower electrode PEL1-3 to form a third lower electrode EL1-3. The third lower electrode EL1-3 may include a third protective layer PTL-3, a third reflective layer RFL-3, and a third conductive layer CDL-3.

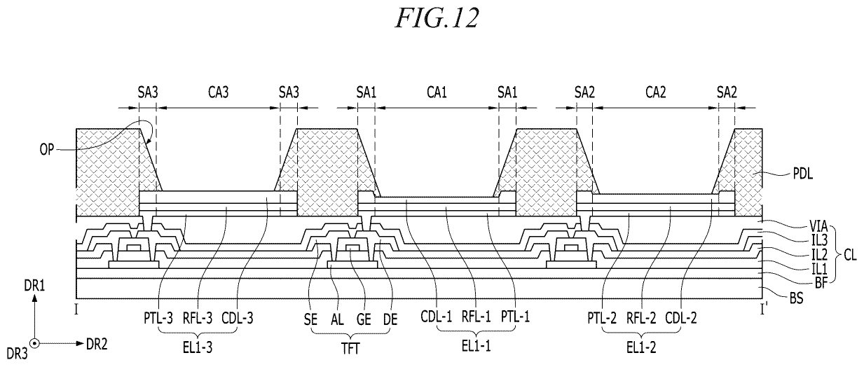

Referring to FIGS. 7 and 12, in the process of forming the pixel defining layer (S500), the pixel defining layer PDL may be formed. The pixel defining layer PDL may cover the top surface of the first lower electrode EL1-1 overlapping the first peripheral region SA1, a portion of the top surface of the first lower electrode EL1-1 overlapping the first central region CA1, the top surface of the second lower electrode EL1-2 overlapping the second peripheral region SA2, and a portion of the top surface of the second lower electrode EL1-2 overlapping the second central region CA2. The pixel defining layer PDL may further cover the top surface of the third lower electrode EL1-3 overlapping the third peripheral region SA3 and a portion of the top surface of the third lower electrode EL1-3 overlapping the third central region CA3.

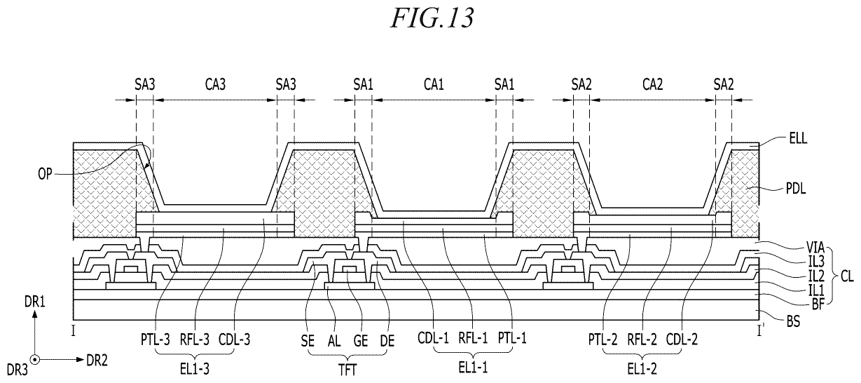

Referring to FIGS. 7 and 13, in the process of forming the display element layer (S600), the display element layer ELL may be formed. The display element layer ELL may be formed on the first through third lower electrodes EL1-1, EL1-2, EL1-3 as well as on the pixel defining layer PDL.

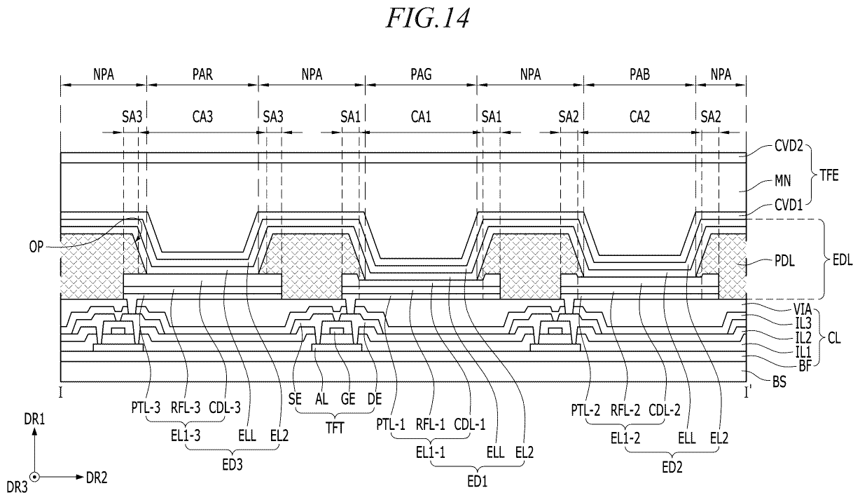

Referring to FIGS. 7 and 14, in the process of forming the upper electrode (S700), an upper electrode EL2 may be formed. The upper electrode EL2 may be formed on the display element layer ELL. As a result, a first light-emitting diode ED1, including the first lower electrode EL1-1, the display element layer ELL, and the upper electrode EL2, may be formed. Similarly, a second light-emitting diode ED2 and a third light-emitting diode ED3 may also be formed. In an embodiment of the disclosure, the method may further include forming an encapsulation layer TFE on the upper electrode EL2, the encapsulation layer TFE including a first inorganic layer CVD1, an organic layer MN, and a second inorganic layer CVD2.

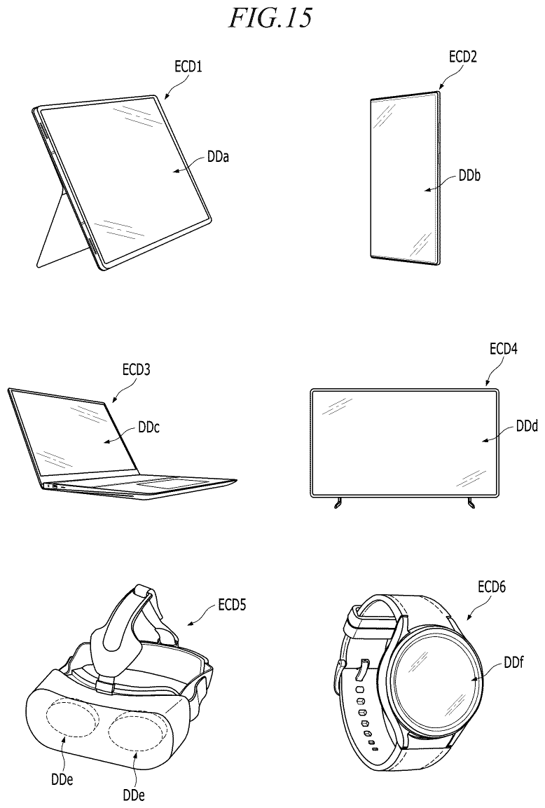

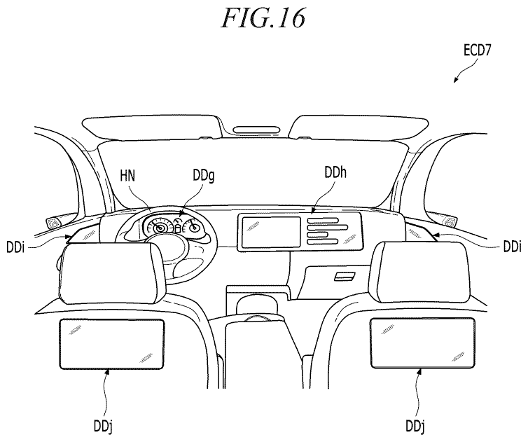

FIGS. 15 and 16 are diagrams illustrating electronic devices to which the display device according to embodiments of the disclosure is applied.

Referring to FIG. 15, a first electronic device ECD1 is a tablet computer including a first display device DDa. A second electronic device ECD2 is a portable terminal including a second display device DDb. A third electronic device ECD3 is a laptop computer including a third display device DDc. A fourth electronic device ECD4 is a television (TV) including a fourth display device DDd. A fifth electronic device ECD5 is a head-mounted display device including a fifth display device DDe. A sixth electronic device ECD6 is a digital watch including a sixth display device DDf.

Referring to FIG. 16, a seventh electronic device ECD7 is a vehicle including seventh through tenth display devices DDg-DDj. Although an automobile is illustrated as the seventh electronic device ECD7 as an example, the disclosure is not limited thereto and may include various types of vehicle or transportation means, such as bicycles, motorcycles, trains, ships, and airplanes.

The seventh display device DDg may be placed in front of the steering wheel HN within the driver's field of view and may be used to display dashboard information such as vehicle speed. The eighth display device DDh may be separate from the seventh display device DDg and placed on the vehicle's dashboard to display control interfaces, audio, temperature, road conditions, and videos. The ninth display device DDi may be placed at the driver and passenger side mirrors and may be utilized as a digital side mirror. The ninth display device DDi may display video captured from the vehicle's exterior. The tenth display device DDj may be placed behind the driver and passenger seats and may display contents, such as videos, to the rear seat passengers.

At least one of the first through tenth display devices DDa-DDj may include the display device DD described with reference to FIGS. 1 and 2, and FIGS. 3A to 3C. At least one of the first through tenth display devices DDa-DDj may also include the display device DD described with reference to FIG. 5 or FIG. 6.

The display devices according to embodiments of the disclosure are not limited to the electronic devices shown in FIGS. 15 and 16 and may also be applied to a variety of electronic devices, such as printers, telephones, wearable devices, digital cameras, camcorders, viewfinders, three-dimensional (3D) displays, video walls comprising tiled displays, theaters, signage, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate on which a plurality of light-emitting regions are defined;
a circuit layer disposed on the substrate, wherein the circuit layer comprises thin-film transistors;
lower electrodes disposed on the circuit layer, electrically connected to the thin-film transistors, and arranged to correspond, respectively, to the plurality of light-emitting regions;
a display element layer disposed on the lower electrodes; and
an upper electrode disposed on the display element layer,
wherein a first lower electrode among the lower electrodes includes a first central region and a first peripheral region surrounding the first central region, which are defined therein, and
wherein a thickness of the first central region of the first lower electrode is smaller than a thickness of the first peripheral region of the first lower electrode.

2. The display device of claim 1, wherein the first lower electrode comprises:
a first protective layer;
a first reflective layer disposed on the first protective layer; and
a first conductive layer disposed on the first reflective layer,
wherein the first conductive layer comprises a first central conductive layer overlapping the first central region and a first peripheral conductive layer overlapping the first peripheral region, and
wherein the first central conductive layer has a smaller thickness than the first peripheral conductive layer.

3. The display device of claim 2, wherein the first conductive layer comprises indium tin oxide (ITO).

4. The display device of claim 2, further comprising a pixel defining layer disposed between the circuit layer and the display element layer,
wherein the pixel defining layer covers the first peripheral conductive layer and a portion of the first central conductive layer connected to the first peripheral conductive layer.

5. The display device of claim 2, wherein a second lower electrode among the lower electrodes includes a second central region and a second peripheral region surrounding the second central region, which are defined therein,
wherein a thickness of the second central region of the second lower electrode is smaller than a thickness of the second peripheral region of the second lower electrode, and
wherein the thickness of the second central region of the second lower electrode is greater than the thickness of the first central region of the first lower electrode.

6. The display device of claim 5, wherein the thickness of the first peripheral region of the first lower electrode is equal to the thickness the second peripheral region of the second lower electrode.

7. The display device of claim 5, wherein the first lower electrode is disposed to correspond to a first light-emitting region among the plurality of light-emitting regions,
wherein the second lower electrode is disposed to correspond to a second light-emitting region among the plurality of light-emitting regions,
wherein the first light-emitting region emits light in a green wavelength band, and
wherein the second light-emitting region emits light in a blue wavelength band.

8. The display device of claim 5, wherein the second lower electrode comprises:
a second protective layer;
a second reflective layer disposed on the second protective layer; and
a second conductive layer disposed on the second reflective layer,
wherein the second conductive layer comprises a second central conductive layer overlapping the second central region and a second peripheral conductive layer overlapping the second peripheral region,
wherein the second central conductive layer has a smaller thickness than the second peripheral conductive layer, and
wherein the second central conductive layer has a greater thickness than the first central conductive layer.

9. The display device of claim 8, wherein a third lower electrode among the lower electrodes includes a third central region and a third peripheral region surrounding the third central region, which are defined therein,
wherein a thickness of the third central region of the third lower electrode is equal to a thickness of the third peripheral region of the third lower electrode, and
wherein the thickness of the third central region of the third lower electrode is greater than the thickness of the second central region of the second lower electrode.

10. The display device of claim 9, wherein the third lower electrode comprises:
a third protective layer;
a third reflective layer disposed on the third protective layer; and
a third conductive layer disposed on the third reflective layer,
wherein the third conductive layer comprises a third central conductive layer overlapping the third central region and a third peripheral conductive layer overlapping the third peripheral region, and
wherein the third central conductive layer and the third peripheral conductive layer have a same thickness as each other.

11. The display device of claim 9, wherein the third lower electrode is disposed to correspond to a third light-emitting region among the plurality of light-emitting regions, and
wherein the third light-emitting region emits light in a red wavelength band.

12. The display device of claim 1, wherein the display element layer comprises a plurality of light-emitting structures and charge generation layers, which are stacked between the lower electrodes and the upper electrode, and
wherein each of the plurality of light-emitting structures comprises a hole functional layer and an electron functional layer with a light-emitting layer disposed therebetween.

13. A method of manufacturing a display device, the method comprising:
preparing a substrate;
forming a circuit layer on the substrate;
forming preliminary lower electrodes on the circuit layer, wherein a first preliminary lower electrode among the preliminary lower electrodes includes a first central region and a first peripheral region surrounding the first central region, which are defined therein; and
forming lower electrodes by etching a portion of the first preliminary lower electrode overlapping the first central region using a mask.

14. The method of manufacturing the display device of claim 13, wherein the forming the preliminary lower electrodes comprises:
forming a preliminary protective layer on the circuit layer;
forming a preliminary reflective layer on the preliminary protective layer;
forming a preliminary conductive layer on the preliminary reflective layer; and
etching the preliminary protective layer, the preliminary reflective layer, and the preliminary conductive layer.

15. The method of manufacturing the display device of claim 14, wherein the first preliminary lower electrode comprises a first preliminary protective layer, a first preliminary reflective layer, and a first preliminary conductive layer, which are defined by patterned portions of the preliminary protective layer, the preliminary reflective layer, and the preliminary conductive layer, respectively, and
wherein the forming the lower electrodes comprises etching a portion of the first preliminary conductive layer of the first preliminary lower electrode.

16. The method of manufacturing the display device of claim 15, wherein a second preliminary lower electrode among the preliminary lower electrodes includes a second central region and a second peripheral region surrounding the second central region, which are defined therein, and
wherein the forming the lower electrodes comprises:
forming a photoresist on the preliminary lower electrodes;
forming a first preliminary photoresist by removing a portion of the photoresist using a halftone mask, wherein the halftone mask exposes a portion of an upper surface of the first preliminary lower electrode overlapping the first central region and allows a portion of the photoresist overlapping the second central region to have a first thickness;
etching a portion of the first preliminary lower electrode to form a first intermediate lower electrode;
forming a second preliminary photoresist by removing a portion of the first preliminary photoresist to expose a portion of an upper surface of the second preliminary lower electrode overlapping the second central region; and
forming a first lower electrode and a second lower electrode by etching a portion of the first intermediate lower electrode and a portion of the second preliminary lower electrode.

17. The method of manufacturing the display device of claim 16, wherein a third preliminary lower electrode among the preliminary lower electrodes includes a third central region and a third peripheral region surrounding the third central region, which are defined therein, and
wherein the forming the first preliminary photoresist comprises not removing portions of the photoresist overlapping the first peripheral region, the second peripheral region, the third peripheral region, and the third central region.

18. The method of manufacturing the display device of claim 17,
wherein in the forming the second preliminary photoresist, the second preliminary photoresist covers an upper surface of the third preliminary lower electrode.

19. The method of manufacturing the display device of claim 18, further comprising:
forming a pixel defining layer to cover an upper surface of the first lower electrode overlapping the first peripheral region and a portion of an upper surface of the first lower electrode overlapping the first central region and to cover an upper surface of the second lower electrode overlapping the second peripheral region and a portion of an upper surface of the second lower electrode overlapping the second central region.

20. An electronic device comprising:
a display device, comprising:
a substrate on which a plurality of light-emitting regions are defined;
a circuit layer disposed on the substrate, wherein the circuit layer comprises thin-film transistors;
lower electrodes disposed on the circuit layer, electrically connected to the thin-film transistors, and arranged to correspond, respectively, to the plurality of light-emitting regions;
a display element layer disposed on the lower electrodes; and
an upper electrode disposed on the display element layer,
wherein a first lower electrode among the lower electrodes includes a first central region and a first peripheral region surrounding the first central region, which are defined therein, and
wherein a thickness of the first central region of the first lower electrode is smaller than a thickness of the first peripheral region of the first lower electrode.
